(19) United States
(12) Patent Application Publication
(10) Pub. No.: US 2023/0361724 A1
(43) Pub. Date: Nov. 9, 2023

(54) SYSTEMS AND METHODS FOR FRONT-END MODULE FILTERING

(71) Applicant: SKYWORKS SOLUTIONS, INC., Irvine, CA (US)

(72) Inventors: Kun Chen, Thousand Oaks, CA (US); Taesong Hwang, Camarillo, CA (US); Haibo Cao, Newbury Park, CA (US); Yu-Jui Lin, Westlake Village, CA (US); Min-Chung Vincent Ho, Newbury Park, CA (US); Aleksey A. Lyalin, Moorpark, CA (US)

(21) Appl. No.: 18/143,168

(22) Filed: May 4, 2023

Related U.S. Application Data
(60) Provisional application No. 63/364,119, filed on May 4, 2022.

(51) Int. Cl. H03F 3/21; H03F 1/56; H03F 3/45

(52) U.S. Cl. CPC H03F 1/565; H03F 3/21; H03F 3/45179; H03F 2200/09; H03F 2200/387; H03F 2200/451; H03F 2203/21139; H03F 2203/45034; H03F 2203/45156

(57) ABSTRACT

According to at least one aspect of the disclosure, a front-end module is provided comprising an input configured to receive a radio-frequency signal, an output configured to be coupled to an antenna, a balun coupled to the output, one or more power amplifiers coupled to the input, and an inverter coupled between the one or more power amplifiers and the balun, the inverter being configured to provide output impedance matching to the one or more power amplifiers.

### CROSS REFERENCE TO RELATED APPLICATIONS

This application claims priority under 35 U.S.C. § 119(e) to U.S. Provisional Application Serial No. 63/364,119, titled “SYSTEMS AND METHODS FOR FRONT-END MODULE FILTERING,” filed on May 4, 2022, which is hereby incorporated by reference in its entirety.

### BACKGROUND

### 1. Field of the Disclosure

At least one example in accordance with the present disclosure relates generally to signal filtering.

### 2. Discussion of Related Art

Wireless communication devices may communicate over various frequencies of the electromagnetic spectrum, including radio frequencies (RF). RF devices may include front-end modules to facilitate wireless RF communication. Front-end modules may include various components including, for example, power amplifiers, transceivers, low-noise amplifiers, antennas, and so forth.

### SUMMARY

According to at least one aspect of the present disclosure, a front-end module is provided comprising an input configured to receive a radio-frequency signal, an output configured to be coupled to an antenna, a balun coupled to the output, one or more power amplifiers coupled to the input, and an inverter coupled between the one or more power amplifiers and the balun, the inverter being configured to provide output impedance matching to the one or more power amplifiers.

In at least one example, the inverter includes a first differential input and a second differential input coupled to the one or more power amplifiers, and a first differential output and a second differential output coupled to the balun. In some examples, the inverter includes a first capacitor having an input coupled to the first differential input and an output coupled to the first differential output, and a second capacitor having an input coupled to the second differential input and an output coupled to the second differential output. In various examples, the inverter includes a first inductor having an input coupled to the first differential input and an output, a second inductor having an input coupled to the output of the first inductor and an output coupled to the first differential output, the first inductor and the second inductor forming a first series combination, a third inductor having an input coupled to the second differential input and an output, and a fourth inductor having an input coupled to the output of the third inductor and an output coupled to the second differential output, the third inductor and the fourth inductor forming a second series combination.

In at least one example, the first capacitor forms a first parallel combination with the first series combination of the first inductor and the second inductor, and the second capacitor forms a second parallel combination with the second series combination of the third inductor and the fourth inductor. In some examples, the first parallel combination presents an open circuit to at least one harmonic of a first fundamental signal received at the first differential input, and the second parallel combination presents an open circuit to at least one harmonic of a second fundamental signal received at the second differential input. In various examples, the first parallel combination presents an open circuit to second-order harmonics of the first fundamental signal and the second parallel combination presents an open circuit to second-order harmonics of the second fundamental signal.

In at least one example, the inverter includes a first capacitor having an input coupled to the first differential input and an output, a first inductor having an input coupled to the output of the first capacitor and an output coupled to the second differential input, the first inductor and the first capacitor forming a first series combination, a second capacitor having an input coupled to the first differential output and an output, and a second inductor having an input coupled to the output of the second capacitor and an output coupled to the second differential output, the second inductor and the second capacitor forming a second series combination. In some examples, the first series combination and the second series combination each present a short circuit to at least one harmonic of at least one of a first fundamental signal received at the first differential input or a second fundamental signal received at the second differential input. In various examples, the first series combination and the second series combination each present a short circuit to a third-order harmonic of at least one of the first fundamental signal or the second fundamental signal.

In at least one example, the balun includes a center tap, the front-end module further comprising a balun matching network coupled to the center tap of the balun. In some examples, the balun matching network includes a first capacitor having an input coupled to the center tap of the balun and an output, a first inductor having an input coupled to the output of the first capacitor and an output coupled to a reference node, the first capacitor and the first inductor forming a first series combination, a second capacitor having an input coupled to the center tap of the balun and an output, and a second inductor having an input coupled to the output of the second capacitor and an output coupled to the reference node, the second capacitor and the second inductor forming a second series combination. In various examples, at least one of the first series combination and the second series combination presents a short circuit to at least one of a fundamental signal at the center tap or at least one harmonic of the fundamental signal.

In at least one example, the first series combination presents a short circuit to the fundamental signal and the second series combination presents a short circuit to a third-order harmonic of the fundamental signal. In some examples, a parallel combination of the first series combination and the second series combination presents an open circuit to at least one harmonic of a fundamental signal at the center tap. In various examples, the parallel combination of the first series combination and the second series combination presents an open circuit to a second-order harmonic of the fundamental signal. In at least one example, the front-end module further includes a first power-amplifier balun and a second power-amplifier balun, the one or more power amplifiers including at least one first power amplifier coupled to the first power-amplifier balun and at least one second power amplifier coupled to the second power-amplifier balun.

According to at least one aspect of the disclosure, a method of processing a radio-frequency signal is provided comprising providing a front-end module having an input configured to receive a radio-frequency signal, an output configured to be coupled to an antenna, a balun coupled to the output, one or more power amplifiers coupled to the input, and an inverter coupled between the one or more power amplifiers and the balun, receiving, by the one or more power amplifiers from the input, the radio-frequency signal, providing, by the one or more power amplifiers, an amplified signal to the inverter, and providing, by the inverter, output impedance matching to the one or more power amplifiers responsive to receiving the amplified signal.

In at least one example, the method further includes providing a balun matching network coupled to a center tap of the balun. In some examples, the method further includes providing, by the balun matching network, output impedance matching to one or more signals conducted by the balun.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a front-end module according to an example;

FIG. 2 illustrates a block diagram of portions of the front-end module according to an example;

FIG. 3 illustrates a schematic diagram of a one-section inverter according to an example;

FIG. 4 illustrates a schematic diagram of a two-section inverter according to an example;

FIG. 5 illustrates a schematic diagram of a balun center-tap matching network according to an example;

FIG. 6 illustrates a schematic diagram of a post-balun matching network according to an example;

FIG. 7 illustrates a schematic diagram of a shunt-capacitor network according to an example; and

FIG. 8 illustrates a schematic diagram of the front-end module according to an example.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

As discussed above, wireless communication devices may include radio-frequency (RF) devices. RF devices often include front-end modules to facilitate RF communication. Front-end modules include several components, such as power amplifiers. Power amplifiers receive an input signal, amplify the input signal based on a gain value, and output an amplified output signal based on the input signal and the gain value.

Performance of a power amplifier is characterized by various metrics. Example performance metrics may include a power-added efficiency (PAE) and/or linearity. In some examples, a power amplifier that is considered “ideal” may exhibit a gain that is constant, that is, does not vary as a magnitude of input power is varied. In this example, the gain may be considered perfectly linear, because the gain is constant. Non-ideal power amplifiers may exhibit a gain that is not linear. For example, the gain of a non-ideal power amplifier may decrease rapidly at or above a certain input-power magnitude referred to as a saturated power (PSAT). A power amplifier that has a substantially linear gain at or within a certain operating point or range may be considered to exhibit favorable linearity.

Non-ideal power amplifiers may not be perfectly efficient due to unintended losses in the power amplifier. For example, some power amplifiers, such as push-pull power amplifiers, may include transformers, such as baluns. A balun may have a leakage inductance. The leakage inductance may introduce inefficiencies in the balun. The power amplifier may include a filter to mitigate or eliminate the inefficiencies in the balun. For example, the power amplifier may include one or more capacitors configured to balance the leakage inductance of the balun. Balancing the leakage inductance may include mitigating or eliminating the losses in the leakage inductance. Accordingly, efficiency is another metric of power-amplifier performance.

PAE and/or linearity may be improved by implementing an efficient matching network for fundamental frequencies and higher-order harmonics, such as second harmonics, third harmonics, and so forth. However, matching-network design may be complex. For example, some power amplifiers’ matching networks include one or more inverters, a balun, and post-balun matching, which may impose challenges in manipulating matching for a fundamental frequency and harmonics thereof. Impedance matching may be particularly difficult where a matching network is implemented far from an output of the power amplifiers because additional impedance may be introduced between the output and the matching network.

Examples disclosed herein provide improved matching networks for power amplifiers in wireless communication devices. In various examples, a matching network includes at least an inverter and matching components coupled to a center tap of a balun. The matching network provides a desired impedance to signals and harmonics thereof. In various examples, components of the matching network are implemented between the power amplifiers and the balun to reduce a complexity of harmonic impedance control. The matching network may include or be coupled to one or more tunable components, such as one or more switchable capacitors, to provide tunable matching. Examples of the disclosure therefore provide improved harmonic impedance control at least in the context of wireless RF devices.

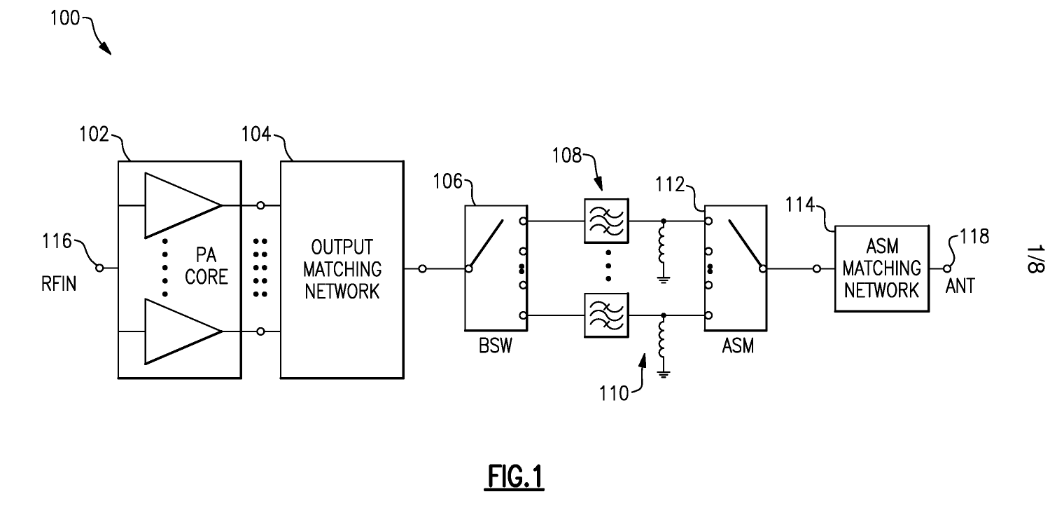

Example power amplifiers may be implemented according to various configurations. For purposes of explanation only, examples are given with respect to push-pull power amplifiers and, in some examples, Doherty push-pull amplifiers. However, the principles of the disclosure are not limited to push-pull power amplifiers. Furthermore, power amplifiers according to the disclosure may be implemented in any of a variety of electronic devices, such as consumer electronics, automobiles, appliances, laptop computers, desktop computers, industrial equipment, and so forth. For purposes of explanation only, examples may be provided in which power amplifiers are implemented in wireless cellular devices, such as smartphones. For example, an example power amplifier may be implemented in a wireless device as discussed below with respect to FIG. 1.

FIG. 1 illustrates a block diagram of a front-end module 100 according to an example. The front-end module 100 may be implemented in a wireless communication device, such as a cellular phone, smart phone, tablet, modem, communication network or any other portable or non-portable device configured for voice and/or data communication. The front-end module 100 may be implemented between a baseband subsystem and one or more antennas of the wireless device. The front-end module 100 may illustrate additional, fewer, or different components than those implemented in certain wireless devices for purposes of explanation, and the principles of the disclosure are not limited to the example of FIG. 1. For example, a wireless device may include components such as a user interface, memory and/or storage, a baseband sub-system, a transceiver, a power-management system, a coupler, a sensor coupled to the coupler, one or more controllers, a low-noise amplifier (LNA), and so forth, which are not illustrated for purposes of explanation.

The front-end module 100 includes a power-amplifier (“PA”) core 102, an output matching network 104, a band switch (“BSW”) 106, one or more duplexers 108 (“duplexers 108”), one or more matching inductors 110 (“inductors 110”), an antenna switch module (“ASM”) 112, an antenna matching network 114, an RF input connection 116 (“RF input 116”), and an antenna output connection 118 (“antenna output 118”). FIG. 1 illustrates aspects of a transmit path, and omits certain aspects of a receive path for purposes of explanation.

The PA core 102 is coupled to the RF input 116 at a first connection, and is coupled to the output matching network 104 at one or more second connections. In some examples, the one or more second connections include several connections (for example, each corresponding to a respective PA) each configured to be coupled to the output matching network 104. The output matching network 104 is coupled to the PA core 102 at one or more first connections, and is coupled to the BSW 106 at a second connection. In some examples, the one or more first connections include several first connections each configured to be coupled to the PA core 102 (for example, each corresponding to a respective PA of the PA core 102).

The BSW 106 is coupled to the output matching network 104 at a first connection, and is coupled to the duplexers 108 at one or more second connections. In some examples, the one or more second connections include several connections each configured to be coupled to a respective duplexer of the duplexers 108. The duplexers 108 are coupled to the BSW 106 at one or more first connections, and are coupled to the inductors 110 and the ASM 112 at one or more second connections. In some examples, the one or more first connections and the one or more second connections include several connections each configured to be coupled to a respective duplexer of the duplexers 108. In various examples, each of the one or more first connections may also be coupled to the BSW 106, and each of the one or more second connections may also be coupled to a respective inductor of the inductors 110 and to the ASM 112.

Each of the inductors 110 is configured to be coupled to a respective duplexer of the duplexers 108 and to the ASM 112 at a respective first connection, and is configured to be coupled to a reference node (for example, a neutral node) at a second connection. The ASM 112 is configured to be coupled to the duplexers 108 and the inductors 110 at one or more first connections, and is configured to be coupled to the antenna matching network 114 at a second connection. In some examples, the one or more first connections includes several connections each configured to be coupled to a respective duplexer of the duplexers 108 and to a respective inductor of the inductors 110.

The antenna matching network 114 is coupled to the ASM 112 at a first connection, and is coupled to the antenna output 118 at a second connection. The RF input 116 is coupled to the PA core 102, and is configured to be coupled to a source of an RF signal. For example, the source of the RF signal may be within a wireless device that the front-end module 100 is implemented in, such as a transceiver or baseband subsystem. The antenna output 118 is coupled to the antenna matching network 114, and is configured to be coupled to at least one antenna. For example, the one or more antennas may be within a wireless device that the front-end module 100 is implemented in, and may be configured to send and/or receive RF signals.

In operation, the front-end module 100 is configured to modulate one or more RF signals received at the RF input 116 to be delivered to one or more antennas via the antenna output 118. Such modulation may include amplification, filtering, and so forth. In some examples, the front-end module 100 may be configured to modulate signals of different power levels and within frequency bands. Accordingly, the front-end module 100 may include several possible signal paths to modulate different signals as desired.

In one example, an input signal (for example, an RF signal) may be received at the RF input 116. For example, the input signal may be received from a baseband subsystem. The input signal may be provided to the PA core 102. The PA core 102 may be implemented according to any of several PA topologies, such as push-pull amplifiers, Doherty amplifiers, Doherty push-pull amplifiers, and so forth, and may include multiple power amplifiers. For example, the PA core 102 may include a power divider configured to divide an RF input signal into two or more phase-shifted signal pairs, and the PA core 102 may include four or more power amplifiers each configured to receive a respective signal, such as a balanced signal.

The PA core 102 can be used to amplify a wide variety of RF or other frequency-band transmission signals. For example, the PA core 102 can receive an enable signal that can be used to pulse the output of one or more power amplifiers to aid in transmitting a wireless local-area-network (WLAN) signal or any other suitable pulsed signal. The PA core 102 can be configured to amplify any of a variety of types of signal, including, for example, 5G signals, a Global System for Mobile (GSM) signal, a code-division multiple-access (CDMA) signal, a W-CDMA signal, a Long-Term-Evolution (LTE) signal, or an EDGE signal. Accordingly, the input signal may be provided to the PA core 102, and the PA core 102 may divide the input signal, amplify the divided signals, and provide power-amplified signals to the output matching network 104.

The output matching network 104 receives the divided, power-amplified signals from the PA core 102 and provides output matching by presenting an impedance that is matched to an output of one or more power amplifiers of the PA core 102. The output matching network 104 may include filtering components such as capacitors, inductors, and so forth, configured to provide desired impedance matching to a received signal. In some examples, the output matching network 104 may include a balun configured to receive two or more signals (for example, balanced signals) and output a single-ended signal. Accordingly, the output matching network 104 may receive power-amplified signals (for example, balanced, power-amplified signals), provide impedance matching to the signals, and output a single-ended signal generated from the power-amplified signals to the BSW 106.

The BSW 106 is configured to receive the single-ended signal from the output matching network 104 and route the single-ended signal to a respective duplexer of the duplexers 108. Each of the duplexers 108 may correspond to a respective frequency band, and the BSW 106 may route the single-ended signal to a duplexer corresponding to the frequency band of the single-ended signal. The duplexer to which the BSW 106 routes the single-ended signal provides the signal to a respective inductor of the inductors 110 and to the ASM 112. As understood by those of ordinary skill in the art, some duplexers may route signals between a transmit path and a receive path. FIG. 1 illustrates aspects of a transmit path, and omits aspects of a receive path for purposes of explanation. In various examples, however, each of the duplexers 108 may include one or more additional connections to couple to a respective receive path including components such as low-noise amplifiers, which are omitted for clarity. In various examples, the front-end module 100 may include or be coupled to a control circuit configured to operate the BSW 106 and/or duplexers 108 to route signals as desired.

The inductors 110 may provide impedance matching to signals output by the duplexers 108. The ASM 112 may route the signals output by the duplexers 108 to the antenna matching network 114. For example, because the BSW 106 may route a signal to one of several paths to a respective duplexer, the ASM 112 may route that signal from the selected path to the antenna matching network 114. In some examples, the front-end module 100 may be connected to several antennas, and the ASM 112 may route a received signal to a desired antenna of the several antennas. The antenna matching network 114 provides impedance matching to signals received from the ASM 112 and outputs the signal to the antenna output 118.

As discussed above, the antenna output 118 may be coupled to at least one antenna, and the signal provided by the antenna output 118 may be transmitted by the at least one antenna. The at least one antenna is configured to transmit and/or receive one or more signals, such that the wireless device may communicate with one or more external devices via the at least one antenna. As discussed above, a transceiver may generate signals for transmission and/or process received signals. In some embodiments, transmission and reception functionalities can be implemented in separate components (for example, a transmit module and a receiving module) or be implemented in the same module.

Accordingly, the front-end module 100 may be configured to transmit and receive wireless signals, such as RF signals, to and from one or more antennas. As discussed above, the output matching network 104 provides output-impedance matching to the PA core 102 at least in part by matching an impedance at an output of the one or more PAs of the PA core 102.

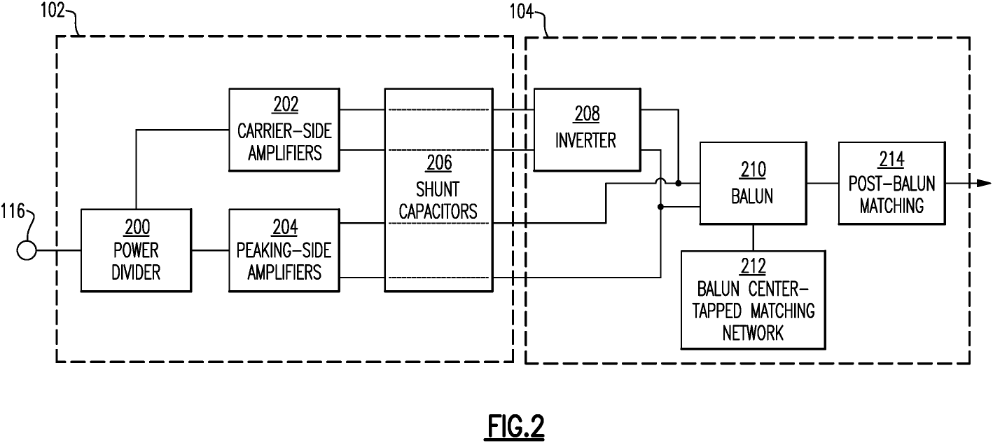

To illustrate the foregoing, FIG. 2 illustrates a block diagram of a portion of the front-end module 100 according to an example, including the PA core 102, the output matching network 104, and the RF input 116. For clarity of explanation and illustration, other aspects of the front-end module 100 are omitted. Although certain sub-components are illustrated as being included in and/or excluded from certain components for purposes of explanation, sub-components may be included in other components in alternate examples.

The PA core 102 includes a power-dividing circuit 200 (“power divider 200”), one or more carrier-side amplifiers 202 (“carrier-side amplifiers 202”), one or more peaking-side amplifiers 204 (“peaking-side amplifiers 204”), and one or more shunt capacitors 206 (“shunt capacitors 206”). The output matching network 104 includes at least one inverter 208 (“inverter 208”), at least one balun 210 (“balun 210”), at least one balun center-tapped matching network 212 (“balun matching network 212”), and at least one post-balun matching network 214 (“post-balun matching network 214”).

The RF input 116 is coupled to the power divider 200 and, as discussed above, may be configured to be coupled to a source of an RF signal. The power divider 200 is coupled to the RF input 116 at a first connection, is coupled to the carrier-side amplifiers 202 at a second connection, and is coupled to the peaking-side amplifiers 204 at a third connection. The carrier-side amplifiers 202 are coupled to the power divider 200 at a first connection, and are coupled to the inverter 208 via the shunt capacitors 206 at one or more second connections. In some examples, the carrier-side amplifiers 202 include a balun configured to receive a single-ended signal and output two signals (for example, two balanced signals), and each of the carrier-side amplifiers 202 include a respective second connection for each of the two signals. The peaking-side amplifiers 204 are coupled to the power divider 200 at a first connection, and are coupled to the balun 210 via the shunt capacitors 206 at one or more second connections. In some examples, the peaking-side amplifiers 204 include a balun configured to receive a single-ended signal and output two signals (for example, two balanced signals), and each of the peaking-side amplifiers 204 include a respective second connection for each of the two signals.

The shunt capacitors 206 are coupled to the carrier-side amplifiers 202, the peaking-side amplifiers 204, the inverter 208, and the balun 210. In some examples, components of the shunt capacitors 206 may be implemented in, or considered to be a component of, other components of the front-end module 100, such as the inverter 208. The inverter 208 is coupled to the carrier-side amplifiers 202 via the shunt capacitors 206 at one or more first connections, and is coupled to the balun 210 at one or more second connections. The balun 210 is coupled to the inverter 208 at one or more first connections, to the peaking-side amplifiers 204 via the shunt capacitors 206 at the one or more first connections, to the balun matching network 212 at a second connection, and to the post-balun matching network 214 at a third connection. The balun matching network 212 is coupled to the balun 210. The post-balun matching network 214 is coupled to the balun 210 at a first connection, and also includes a section connection which may be coupled to, for example, the BSW 106.

An RF signal received at the RF input 116 may be provided to the power divider 200. The power divider 200 may divide the received signal into two phase-shifted signals. For example, the power divider 200 may divide the received signal into a carrier signal and a peaking signal having voltage waveforms offset by 90° (for example, when the two outputs of the PA core 102 see the same load impedance when output power is at maximum), provide the carrier signal to the carrier-side amplifiers 202, and provide the peaking signal to the peaking-side amplifiers 204. The carrier-side amplifiers 202 amplify the carrier signal. In some examples, the carrier signal is a single-ended signal, and the carrier-side amplifiers 202 include a balun to convert the single-ended signal to two signals (for example, two balanced signals), amplify the two signals, and output the amplified signals to the inverter 208 via the shunt capacitors 206. The peaking-side amplifiers 204 amplify the peaking signal. In some examples, the peaking signal is a single-ended signal, and the peaking-side amplifiers 204 include a balun to convert the single-ended signal to two signals (for example, two balanced signals), amplify the two signals, and output the amplified signals to the balun 210 via the shunt capacitors 206.

The shunt capacitors 206 may shunt the amplified carrier signals (for example, amplified, balanced carrier signals) and/or the amplified peaking signals (for example, amplified, balanced peaking signals). For example, the shunt capacitors 206 may shunt harmonics of the signals to a neutral node, and/or may shunt the signals between the differential outputs of the carrier-side amplifiers 202 and the outputs of the peaking-side amplifiers 204. The shunt capacitors 206 may improve balance and symmetry between the received signals such that, for example, harmonics on one pair of balanced lines do not significantly adversely impact performance on another set of balanced lines.

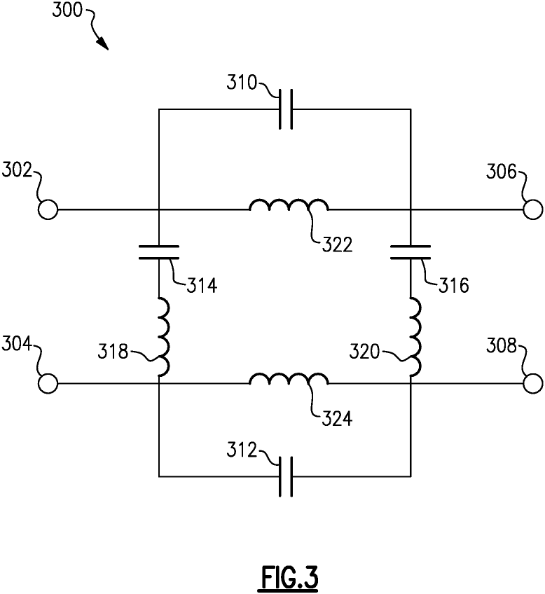

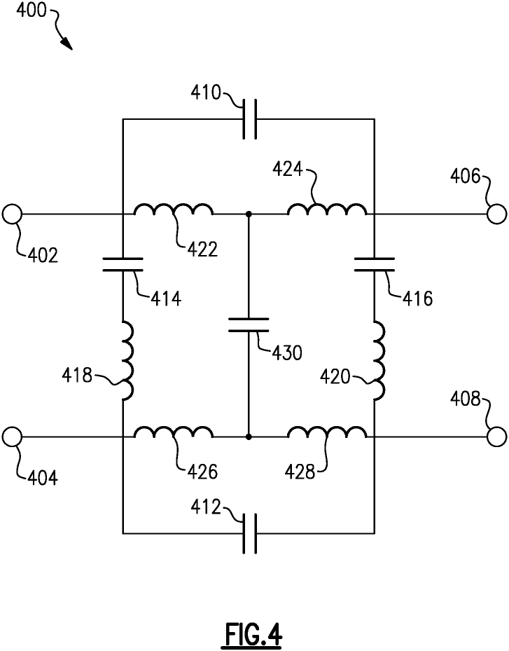

The inverter 208 receives the amplified carrier signals (for example, amplified, balanced carrier signals) from the carrier-side amplifiers 202. Inverters may be implemented to aid in impedance matching inasmuch as the input impedance of an inverter which is terminated in an impedance Z_{L} is

$${Z}_{0}^{2} / {Z}_{L} ,$$

where Z₀ is the characteristic impedance of the inverter when the inverter is modeled as a quarter-wave transmission line. As discussed in greater detail below with respect to FIGS. 3 and 4, the inverter 208 may be implemented in accordance with a pi-matching-network topology to present a desired impedance to the carrier signals. The inverter 208 then provides the carrier signals to the balun 210.

The balun 210 receives the amplified carrier signal and the amplified peaking signal from the inverter 208 and the peaking-side amplifiers 204, respectively. In some examples, the amplified carrier signal and the amplified peaking signal may be balanced when Pout is at maximum. The balun 210 converts the two input signals to a single-ended signal, and provides the single-ended signal to the post-balun matching network 214. The balun matching network 212 may provide impedance matching at a center tap of the balun 210 to improve balance and symmetry of the signals received at the balun 210. The post-balun matching network 214 may provide impedance matching to the single-ended signal at the output of the balun 210 and provide the single-ended signal to, for example, the BSW 106.

As discussed above, the inverter 208 may be implemented in accordance with a pi-matching-network topology to present a desired impedance to the carrier signals. FIG. 3 illustrates a schematic diagram of a one-section inverter 300 (“inverter 300”) according to an example. The inverter 300 may provide an example of the inverter 208. In some examples, the inverter 300 includes components of other portions of the front-end module 100. For example, the inverter 300 may include one or more components of the PA core 102, such as the shunt capacitors 206.

The inverter 300 includes a first differential-signal input 302, a second differential-signal input 304, a first differential-signal output 306, a second differential-signal output 308, a positive crossing capacitor 310, a negative crossing capacitor 312, a first inverter capacitor 314, a second inverter capacitor 316, a first inverter inductor 318, a second inverter inductor 320, a third inverter inductor 322, and a fourth inverter inductor 324. In various examples, the positive crossing capacitor 310 and/or the negative crossing capacitor 312 are components of the shunt capacitors 206, and are illustrated as part of the inverter 300 for purposes of explanation.

The first differential-signal input 302 is coupled to the positive crossing capacitor 310, the first inverter capacitor 314, and the third inverter inductor 322, and is configured to be coupled to a source of a first differential signal, such as the carrier-side amplifiers 202. The second differential-signal input 304 is coupled to the negative crossing capacitor 312, the first inverter inductor 318, and the fourth inverter inductor 324, and is configured to be coupled to a source of a second differential signal, such as the carrier-side amplifiers 202.

The first differential-signal output 306 is coupled to the positive crossing capacitor 310, the second inverter capacitor 316, and the third inverter inductor 322, and is configured to be coupled to a balun, such as the balun 210. The second differential-signal output 308 is coupled to the negative crossing capacitor 312, the fourth inverter inductor 324, and the second inverter inductor 320, and is configured to be coupled to a balun, such as the balun 210.

The positive crossing capacitor 310 is coupled to the first differential-signal input 302 and the first inverter capacitor 314 at a first connection, is coupled to the first differential-signal output 306 and the second inverter capacitor 316 at a second connection, and is coupled in parallel with the third inverter inductor 322. The negative crossing capacitor 312 is coupled to the second differential-signal input 304 and the first inverter inductor 318 at a first connection, is coupled to the second differential-signal output 308 and the second inverter inductor 320 at a second connection, and is coupled in parallel with the fourth inverter inductor 324.

The first inverter capacitor 314 is coupled to the first differential-signal input 302, the positive crossing capacitor 310, and the third inverter inductor 322 at a first connection, and is coupled to the first inverter inductor 318 at a second connection. The second inverter capacitor 316 is coupled to the first differential-signal output 306, the positive crossing capacitor 310, and the third inverter inductor 322 at a first connection, and is coupled to the second inverter inductor 320 at a second connection.

The first inverter inductor 318 is coupled to the first inverter capacitor 314 at a first connection, and is coupled to the second differential-signal input 304, the negative crossing capacitor 312, and the fourth inverter inductor 324 at a second connection. The second inverter inductor 320 is coupled to the second inverter capacitor 316 at a first connection, and is coupled to the second differential-signal output 308, the negative crossing capacitor 312, and the fourth inverter inductor 324 at a second connection.

The third inverter inductor 322 is coupled to the first differential-signal input 302 and the first inverter capacitor 314 at a first connection, is coupled to the first differential-signal output 306 and the second inverter capacitor 316 at a second connection, and is coupled in parallel with the positive crossing capacitor 310. The fourth inverter inductor 324 is coupled to the second differential-signal input 304 and the first inverter inductor 318 at a first connection, is coupled to the second differential-signal output 308 and the second inverter inductor 320 at a second connection, and is coupled in parallel with the negative crossing capacitor 312.

The inverter 300 presents a desired impedance to differential signals received at the differential-signal inputs 302, 304. The desired impedance may vary based on a frequency of the differential signals. For example, an impedance presented to lower-frequency signals, such as fundamental signals and second-order harmonics, may be different than an impedance presented to higher-frequency signals, such as third-order harmonics.

At lower frequencies (for example, fundamental signals and second-order harmonics), the parallel combination of the positive crossing capacitor 310 and the third inverter inductor 322 may present a relatively high impedance to the lower-frequency signals. For example, the positive crossing capacitor 310 may appear approximately as an open circuit. The parallel combination of the negative crossing capacitor 312 and the fourth inverter inductor 324 may similarly present a relatively high impedance to the lower-frequency signals. For example, the negative crossing capacitor 312 may appear approximately as an open circuit.

At higher frequencies (for example, third-order harmonics), the series combination of the first inverter capacitor 314 and the first inverter inductor 318 may present a relatively low impedance to the higher-frequency signals. For example, the first inverter capacitor 314 may appear approximately as a short circuit. The series combination of the second inverter capacitor 316 and the second inverter inductor 320 may similarly present a relatively low impedance to the higher-frequency signals. For example, the second inverter capacitor 316 may appear approximately as a short circuit.

As discussed above, the inverter 300 may be an example of the inverter 208 and may be considered a one-section inverter. In various examples, the inverter 208 may be implemented as a multi-section inverter. For example, the principles of the one-section inverter 300 may be expanded to include additional sections.

FIG. 4 illustrates a schematic diagram of a two-section inverter 400 (“inverter 400”) according to an example. The inverter 400 may provide an example of the inverter 208. In some examples, the inverter 400 includes components of other aspects of the front-end module 100. For example, the inverter 400 may include one or more components of the PA core 102, such as the shunt capacitors 206.

The inverter 400 includes a first differential-signal input 402, a second differential-signal input 404, a first differential-signal output 406, a second differential-signal output 408, a positive crossing capacitor 410, a negative crossing capacitor 412, a first inverter capacitor 414, a second inverter capacitor 416, a first inverter inductor 418, a second inverter inductor 420, a third inverter inductor 422, a fourth inverter inductor 424, a fifth inverter inductor 426, a sixth inverter inductor 428, and a common-mode capacitor 430. In various examples, the positive crossing capacitor 410 and/or the negative crossing capacitor 412 may be components of the shunt capacitors 206, and may be illustrated as part of the inverter 400 for purposes of explanation. In some examples, the capacitors 410, 412 are components of the inverter 400 in addition to, or in lieu of, being components of the shunt capacitors 206.

The first differential-signal input 402 is coupled to the positive crossing capacitor 410, the first inverter capacitor 414, and the third inverter inductor 422, and is configured to be coupled to a source of a first differential signal, such as the carrier-side amplifiers 202. The second differential-signal input 404 is coupled to the negative crossing capacitor 412, the first inverter inductor 418, and the fifth inverter inductor 426, and is configured to be coupled to a source of a second differential signal, such as the carrier-side amplifiers 202.

The first differential-signal output 406 is coupled to the positive crossing capacitor 410, the second inverter capacitor 416, and the fourth inverter inductor 424, and is configured to be coupled to a balun, such as the balun 210. The second differential-signal output 408 is coupled to the negative crossing capacitor 412, the second inverter inductor 420, and the sixth inverter inductor 428, and is configured to be coupled to a balun, such as the balun 210.

The positive crossing capacitor 410 is coupled to the first differential-signal input 402, the first inverter capacitor 414, and the third inverter inductor 422 at a first connection, and is coupled to the first differential-signal output 406, the second inverter capacitor 416, and the fourth inverter inductor 424 at a second connection. In some examples, the third inverter inductor 422 and the fourth inverter inductor 424 may be considered to be coupled in series, and the positive crossing capacitor 410 may be coupled in parallel with a series combination of the inductors 422, 424. The negative crossing capacitor 412 is coupled to the second differential-signal input 404, the first inverter inductor 418, and the fifth inverter inductor 426 at a first connection, and is coupled to the second differential-signal output 408, the second inverter inductor 420, and the sixth inverter inductor 428 at a second connection. In some examples, the fifth inverter inductor 426 and the sixth inverter inductor 428 may be considered to be coupled in series, and the negative crossing capacitor 412 may be coupled in parallel with a series combination of the inductors 426, 428.

The first inverter capacitor 414 is coupled to the first differential-signal input 402, the positive crossing capacitor 410, and the third inverter inductor 422 at a first connection, and is coupled to the first inverter inductor 418 at a second connection. The second inverter capacitor 416 is coupled to the first differential-signal output 406, the positive crossing capacitor 410, and the fourth inverter inductor 424 at a first connection, and is coupled to the second inverter inductor 420 at a second connection.

The first inverter inductor 418 is coupled to the first inverter capacitor 414 at a first connection, and is coupled to the second differential-signal input 404, the negative crossing capacitor 412, and the fifth inverter inductor 426 at a second connection. The second inverter inductor 420 is coupled to the second inverter capacitor 416 at a first connection, and is coupled to the second differential-signal output 408, the negative crossing capacitor 412, and the sixth inverter inductor 428 at a second connection.

The third inverter inductor 422 is coupled to the first differential-signal input 402, the positive crossing capacitor 410, and the first inverter capacitor 414 at a first connection, and is coupled to the fourth inverter inductor 424 and the common-mode capacitor 430 at a second connection. The fourth inverter inductor 424 is coupled to the third inverter inductor 422 and the common-mode capacitor 430 at a first connection, and is coupled to the first differential-signal output 406, the positive crossing capacitor 410, and the second inverter capacitor 416 at a second connection.

The fifth inverter inductor 426 is coupled to the second differential-signal input 404, the first inverter inductor 418, and the negative crossing capacitor 412 at a first connection, and is coupled to the sixth inverter inductor 428 and the common-mode capacitor 430 at a second connection. The sixth inverter inductor 428 is coupled to the fifth inverter inductor 426 and the common-mode capacitor 430 at a first connection, and is coupled to the second differential-signal output 408, the negative crossing capacitor 412, and the second inverter inductor 420 at a second connection. The common-mode capacitor 430 is coupled to the third inverter inductor 422 and the fourth inverter inductor 424 at a first connection, and is coupled to the fifth inverter inductor 426 and the sixth inverter inductor 428 at a second connection.

The inverter 400 presents a desired impedance to differential signals received at the differential-signal inputs 402, 404. The desired impedance may vary based on a frequency of the differential signals. For example, an impedance presented to lower-frequency signals, such as fundamental signals and second-order harmonics, may be different than an impedance presented to higher-frequency signals, such as third-order harmonics.

The common-mode capacitor 430 may behave approximately as an open circuit to common-mode signals such that the positive crossing capacitor 410 approximately forms a parallel combination with a series combination of the third inverter inductor 422 and the fourth inverter inductor 424, and the negative crossing capacitor 412 approximately forms a parallel combination with a series combination of the fifth inverter inductor 426 and the sixth inverter inductor 428.

At lower frequencies (for example, fundamental signals and second-order harmonics), the approximately parallel combination of the positive crossing capacitor 410 with the approximately series combination of the third inverter inductor 422 and the fourth inverter inductor 424 may present a relatively high impedance to the lower-frequency signals. For example, the positive crossing capacitor 410 may appear approximately as an open circuit. The approximately parallel combination of the negative crossing capacitor 412 with the approximately series combination of the fifth inverter inductor 426 and the sixth inverter inductor 428 may similarly present a relatively high impedance to the lower-frequency signals. For example, the negative crossing capacitor 412 may appear approximately as an open circuit.

At higher frequencies (for example, third-order harmonics), the series combination of the first inverter capacitor 414 and the first inverter inductor 418 may present a relatively low impedance to the higher-frequency signals. For example, the first inverter capacitor 414 may appear approximately as a short circuit. The series combination of the second inverter capacitor 416 and the fourth inverter inductor 424 may similarly present a relatively low impedance to the higher-frequency signals. For example, the second inverter capacitor 416 may appear approximately as a short circuit.

Accordingly, the inverter 208 may be implemented in connection with one or more inverter sections. Higher-order inverters may be implemented by adding additional inverter sections until a desired number of sections is reached. In some examples, one or more components of the front-end module 100 may be tunable. For example, the positive crossing capacitors 310, 410 and/or the negative crossing capacitors 312, 412 may be tunable such that a capacitance value of the capacitors 310, 312, 410, 412 may be adjustable. In one example, the capacitors 310, 312, 410, 412 may be tuned based on a frequency band of a signal that the front-end module 100 is processing. In some examples, one or more of the capacitors 310, 312, 410, 412 may not be tunable if, for example, the front-end module 100 does not process signals across a wide range of frequency bands. In various examples, additional and/or alternate components of the front-end module 100 may be tunable.

As discussed above, the inverter 208 may be implemented at an input of the balun 210. It may be advantageous to implement the inverter 208 closer to the PA core 102 (and, in particular, to the carrier-side amplifiers 202) to match an impedance at the output of the PA core 102 amplifiers as closely as possible. Implementing the inverter 208 farther from the PA core 102, such as after the balun 210, may make impedance matching more complex and/or less accurate. In various examples, the balun matching network 212 and the post-balun matching network 214 also provide additional matching functionality.

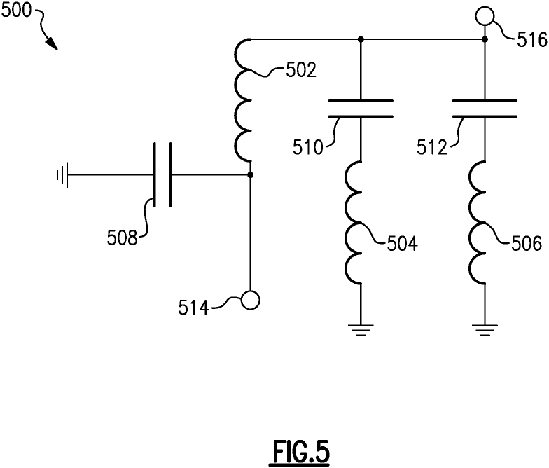

FIG. 5 illustrates a schematic diagram of a balun matching network 500 according to an example. The balun matching network 500 may provide an example of the balun matching network 212. In some examples, the balun matching network 500 includes components of other aspects of the front-end module 100. The balun matching network 500 includes a first inductor 502, a second inductor 504, a third inductor 506, a first capacitor 508, a second capacitor 510, a third capacitor 512, a voltage-source connection 514, and a balun connection 516.

The first inductor 502 is coupled to the second capacitor 510, the third capacitor 512, and the balun connection 516 at a first connection, and is coupled to the first capacitor 508 and the voltage-source connection 514 at a second connection. The second inductor 504 is coupled to the second capacitor 510 at a first connection, and is coupled to a reference node (for example, a neutral node) at a second connection. The third inductor 506 is coupled to the third capacitor 512 at a first connection, and is coupled to a reference node (for example, a neutral node) at a second connection.

The first capacitor 508 is coupled to the first inductor 502 and the voltage-source connection 514 at a first connection, and is coupled to a reference node (for example, a neutral node) at a second connection. The second capacitor 510 is coupled to the first inductor 502, the third capacitor 512, and the balun connection 516 at a first connection, and is coupled to the second inductor 504 at a second connection. The third capacitor 512 is coupled to the first inductor 502, the second capacitor 510, and the balun connection 516 at a first connection, and is coupled to the third inductor 506 at a second connection.

The voltage-source connection 514 is coupled to the first inductor 502 and the first capacitor 508, and is configured to be coupled to a voltage source. The balun connection 516 is coupled to the first inductor 502, the second capacitor 510, and the third capacitor 512, and is configured to be coupled to a balun. For example, the balun connection 516 may be center tapped to the balun 210.

The balun matching network 500 may be configured to balance a balun (and signals conducted thereby) to which the balun matching network 500 is coupled. For example, the balun matching network 500 may improve the symmetry of signals received at a first input of the balun 210 and at a second input of the balun 210. A capacitance of the capacitors 510, 512 and an inductance of the inductors 504, 506 may be selected to present a desired impedance to signals at the center tap of the balun 210.

The series combination of the second capacitor 510 and the second inductor 504 may be configured to present an approximately short circuit to higher-frequency signals (for example, third-order harmonics). For example, a capacitance value of the second capacitor 510 and an inductance value of the second inductor 504 may be selected such that the impedance of the series combination at the higher-frequency signals is approximately a short circuit to the reference node. Higher-frequency signals may therefore be shorted to, in one example, a neutral node to remove harmonics from a balun, such as the balun 210.

The series combination of the third capacitor 512 and the third inductor 506 may be configured to present an approximately short circuit to lower-frequency signals (for example, fundamental signals). For example, a capacitance value of the third capacitor 512 and an inductance value of the third inductor 506 may be selected such that the impedance of the series combination at the lower-frequency signals is approximately a short circuit to the reference node. Lower-frequency signals may therefore be shorted to, in one example, a neutral node to improve balance at a balun, such as the balun 210.

At mid-range frequencies (for example, second-order harmonics), an impedance of the series combination of the second capacitor 510 and the second inductor 504 may be dominated by the second capacitor 510, and an impedance of the series combination of the third capacitor 512 and the third inductor 506 may be dominated by the third inductor 506 such that the overall combination of the elements 504, 506, 510, 512 presents an approximately open circuit to mid-range-frequency signals. For example, capacitance values of the capacitors 510, 512 and inductance values of the inductors 504, 506 may be selected such that a parallel combination of the series combination of the second inductor 504 and the second capacitor 510 with the series combination of the third inductor 506 and the third capacitor 512 appears approximately as a high-impedance (for example, open circuit) parallel combination of the second capacitor 510 and the third inductor 506.

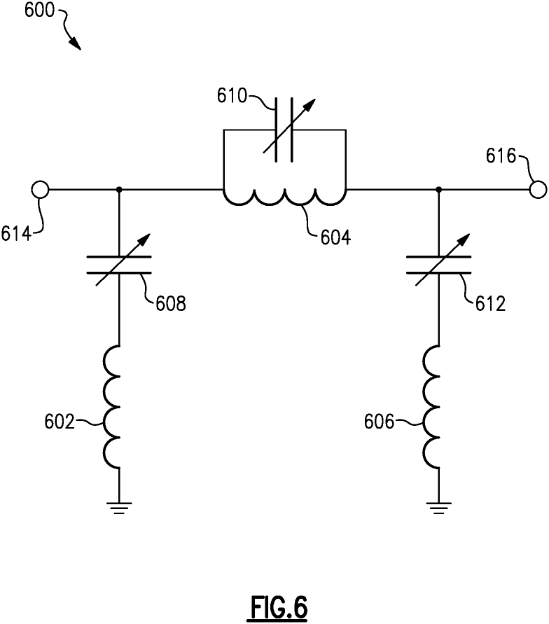

FIG. 6 illustrates a schematic diagram of a post-balun matching network 600 according to an example. The post-balun matching network 600 may be an example of the post-balun matching network 214. In some examples, the post-balun matching network 600 includes components of other aspects of the front-end module 100. The post-balun matching network 600 includes a first inductor 602, a second inductor 604, a third inductor 606, a first capacitor 608, a second capacitor 610, a third capacitor 612, a balun connection 614, and a BSW connection 616.

The first inductor 602 is coupled to the first capacitor 608 at a first connection, and is coupled to a reference node (for example, a neutral node) at a second connection. The second inductor 604 is coupled to the balun connection 614 and the first capacitor 608 at a first connection, is coupled to the third capacitor 612 and the BSW connection 616 at a second connection, and is coupled in parallel with the second capacitor 610. The third inductor 606 is coupled to the third capacitor 612 at a first connection, and is coupled to a reference node (for example, a neutral node) at a second connection.

The first capacitor 608 is coupled to the balun connection 614, the second inductor 604, and the second capacitor 610 at a first connection, and is coupled to the first inductor 602 at a second connection. The second capacitor 610 is coupled to the balun connection 614 and the first capacitor 608 at a first connection, is coupled to the BSW connection 616 and the third capacitor 612 at a second connection, and is coupled in parallel with the second inductor 604. The third capacitor 612 is coupled to the BSW connection 616, the second inductor 604, and the second capacitor 610 at a first connection, and is coupled to the third inductor 606 at a second connection.

The balun connection 614 is coupled to the first capacitor 608, the second capacitor 610, and the second inductor 604, and is configured to be coupled to an output of a balun, such as the balun 210. The BSW connection 616 is coupled to the second capacitor 610, the third capacitor 612, and the second inductor 604, and is configured to be coupled to an input of a BSW, such as the BSW 106.

A series combination of the first inductor 602 and the first capacitor 608, and/or a series combination of the third inductor 606 and the third capacitor 612, may each act as a notch filter for a respective frequency range. For example, the series combination of the first inductor 602 and the first capacitor 608 may act as a notch filter to present a low impedance (for example, approximately a short circuit) to a harmonic signal (for example, third-order or fourth-order harmonics) and thereby short the harmonic signal to ground. Similarly, the series combination of the third inductor 606 and the third capacitor 612 may act as a notch filter to present a low impedance (for example, approximately a short circuit) to a harmonic signal (for example, fourth-order or third-order harmonics) and thereby short the harmonic signal to ground.

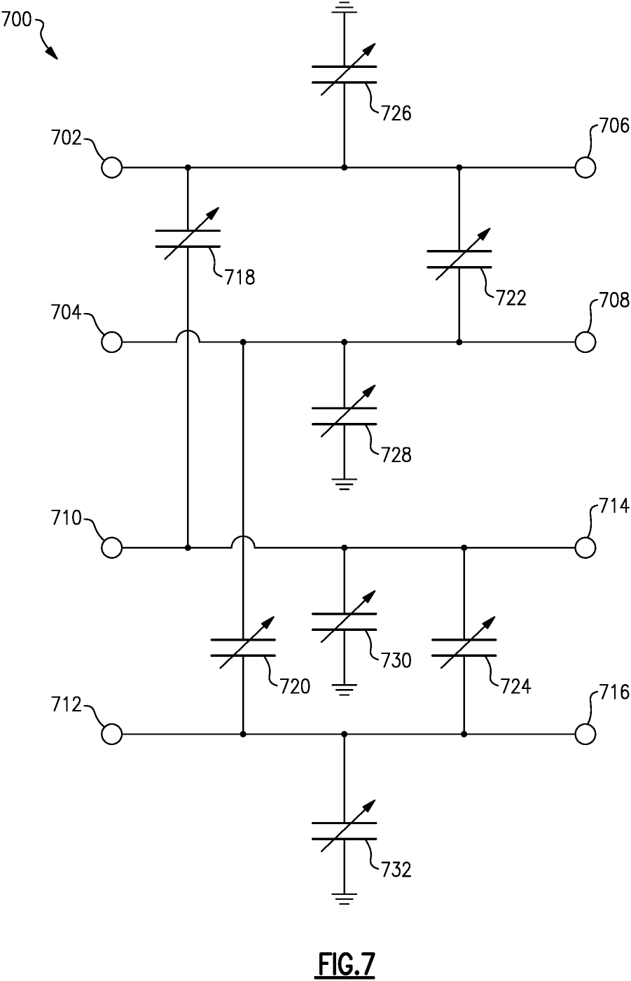

FIG. 7 illustrates a schematic diagram of a shunt-capacitor network 700 according to an example. The shunt-capacitor network 700 may be an example of the shunt capacitors 206. The shunt-capacitor network 700 includes a first carrier-side input 702, a second carrier-side input 704, a first carrier-side output 706, a second carrier-side output 708, a first peaking-side input 710, a second peaking-side input 712, a first peaking-side output 714, a second peaking-side output 716, a positive crossing capacitor 718, a negative crossing capacitor 720, a carrier-side common-mode capacitor 722, a peaking-side common-mode capacitor 724, a positive carrier capacitor 726, a negative carrier capacitor 728, a positive peaking capacitor 730, and a negative peaking capacitor 732.

The first carrier-side input 702 is coupled to the first carrier-side output 706, the positive crossing capacitor 718, the carrier-side common-mode capacitor 722, and the positive carrier capacitor 726, and is configured to be coupled to a source of a positive carrier differential signal, such as a first power amplifier of the carrier-side amplifiers 202. The second carrier-side input 704 is coupled to the second carrier-side output 708, the negative crossing capacitor 720, the carrier-side common-mode capacitor 722, and the negative carrier capacitor 728, and is configured to be coupled to a source of a negative carrier differential signal, such as a second power amplifier of the carrier-side amplifiers 202.

The first carrier-side output 706 is coupled to the first carrier-side input 702, the positive crossing capacitor 718, the carrier-side common-mode capacitor 722, and the positive carrier capacitor 726, and is configured to be coupled to an inverter, such as the inverter 208. In various examples, the first carrier-side output 706 may be coupled to the first differential-signal input 302 or the first differential-signal input 402. The second carrier-side output 708 is coupled to the second carrier-side input 704, the negative crossing capacitor 720, the negative carrier capacitor 728, and the carrier-side common-mode capacitor 722, and is configured to be coupled to an inverter, such as the inverter 208. In various examples, the second carrier-side output 708 may be coupled to the second differential-signal input 304 or the second differential-signal input 404.

The first peaking-side input 710 is coupled to the first peaking-side output 714, the positive crossing capacitor 718, the peaking-side common-mode capacitor 724, and the positive peaking capacitor 730, and is configured to be coupled to a source of a positive peaking differential signal, such as a first power amplifier of the peaking-side amplifiers 204. The second peaking-side input 712 is coupled to the second peaking-side output 716, the negative crossing capacitor 720, the negative peaking capacitor 732, and the peaking-side common-mode capacitor 724, and is configured to be coupled to a source of a negative peaking differential signal, such as a second power amplifier of the peaking-side amplifiers 204.

The first peaking-side output 714 is coupled to the first peaking-side input 710, the positive crossing capacitor 718, the peaking-side common-mode capacitor 724, and the positive peaking capacitor 730, and is configured to be coupled to a balun, such as the balun 210. In various examples, the first peaking-side output 714 may be coupled to a first connection of the balun 210. The second peaking-side output 716 is coupled to the second peaking-side input 712, the negative crossing capacitor 720, the peaking-side common-mode capacitor 724, and the negative peaking capacitor 732, and is configured to be coupled to a balun, such as the balun 210. In various examples, the second peaking-side output 716 may be coupled to a second connection of the balun 210.

The positive crossing capacitor 718 is coupled to the first carrier-side input 702, the positive carrier capacitor 726, the carrier-side common-mode capacitor 722, and the first carrier-side output 706 at a first connection, and is coupled to the first peaking-side input 710, the first peaking-side output 714, the peaking-side common-mode capacitor 724, and the positive peaking capacitor 730 at a second connection. In various examples, the positive crossing capacitor 718 may be an example of the positive crossing capacitor 310 and/or the positive crossing capacitor 410 and may be considered to be a component of the inverters 300, 400 in addition to, or in lieu of, the shunt-capacitor network 700.

The negative crossing capacitor 720 is coupled to the second carrier-side input 704, the negative carrier capacitor 728, the carrier-side common-mode capacitor 722, and the second carrier-side output 708 at a first connection, and is coupled to the second peaking-side input 712, the second peaking-side output 716, the peaking-side common-mode capacitor 724, and the negative peaking capacitor 732 at a second connection. In various examples, the negative crossing capacitor 720 may be an example of the negative crossing capacitor 312 and/or the negative crossing capacitor 412 and may be considered to be a component of the inverters 300, 400 in addition to, or in lieu of, the shunt-capacitor network 700.

The carrier-side common-mode capacitor 722 is coupled to the first carrier-side input 702, the first carrier-side output 706, the positive crossing capacitor 718, and the positive carrier capacitor 726 at a first connection, and is coupled to the second carrier-side input 704, the second carrier-side output 708, the negative crossing capacitor 720, and the negative carrier capacitor 728 at a second connection. The peaking-side common-mode capacitor 724 is coupled to the first peaking-side input 710, the first peaking-side output 714, the positive crossing capacitor 718, and the positive peaking capacitor 730 at a first connection, and is coupled to the second peaking-side input 712, the second peaking-side output 716, the negative crossing capacitor 720, and the negative peaking capacitor 732 at a second connection.

The positive carrier capacitor 726 is coupled to a reference node (for example, a neutral node) at a first connection, and is coupled to the first carrier-side input 702, the first carrier-side output 706, the positive crossing capacitor 718, and the carrier-side common-mode capacitor 722 at a second connection. The negative carrier capacitor 728 is coupled to the second carrier-side input 704, the second carrier-side output 708, the negative crossing capacitor 720, and the carrier-side common-mode capacitor 722 at a first connection, and is coupled to a reference node (for example, a neutral node) at a second connection.

The positive peaking capacitor 730 is coupled to the first peaking-side input 710, the first peaking-side output 714, the positive crossing capacitor 718, and the peaking-side common-mode capacitor 724 at a first connection, and is coupled to a reference node (for example, a neutral node) at a second connection. The negative peaking capacitor 732 is coupled to the second peaking-side input 712, the second peaking-side output 716, the negative crossing capacitor 720, and the peaking-side common-mode capacitor 724 at a first connection, and is coupled to a reference node (for example, a neutral node) at a second connection.

As discussed above, one or more of the capacitors 718-732 may be implemented to shunt signals as desired. For example, because an impedance of capacitors decreases as frequency increases, the capacitors 726-732 may short high-frequency harmonics to a reference node, such as ground. The common-mode capacitors 722, 724 may improve balance on the carrier side and peaking side, respectively. The crossing capacitors 718, 720, as discussed above, may operate with and/or be considered components of the inverter 208 to present a desired impedance to received signals.

In various examples, one or more of the capacitors 718-732 may be tunable to a desired capacitance value. In some examples, all of the capacitors 718-732 may be tunable, and in other examples, fewer than all of the capacitors 718-732 may be tunable. In various examples, one or more of the capacitors 718-732 may not be tunable where, for example, a small number of frequency bands are handled by the shunt-capacitor network 700 and fixed capacitance values may therefore be acceptable. In other examples, all of the capacitors 718-732 may be tunable even where a small number of frequency bands are handled by the shunt-capacitor network 700. In some examples, the front-end module 100 includes, or is configured to be coupled to, a control circuit configured to tune one or more capacitors to a desired capacitance value by sending one or more control signals to the capacitors.

As discussed above, one or more components of the shunt-capacitor network 700 may be considered to be part of one or more other entities. For example, one or more capacitors of the shunt-capacitor network 700, such as one or more of the positive crossing capacitor 718, the negative crossing capacitor 720, the carrier-side common-mode capacitor 722, and/or the peaking-side common-mode capacitor 724, may be considered to be part of the inverter 208 in addition to, or in lieu of, being part of the shunt-capacitor network 700. Accordingly, no limitation is implied by the capacitors 718-732 being illustrated as components of the shunt-capacitor network 700.

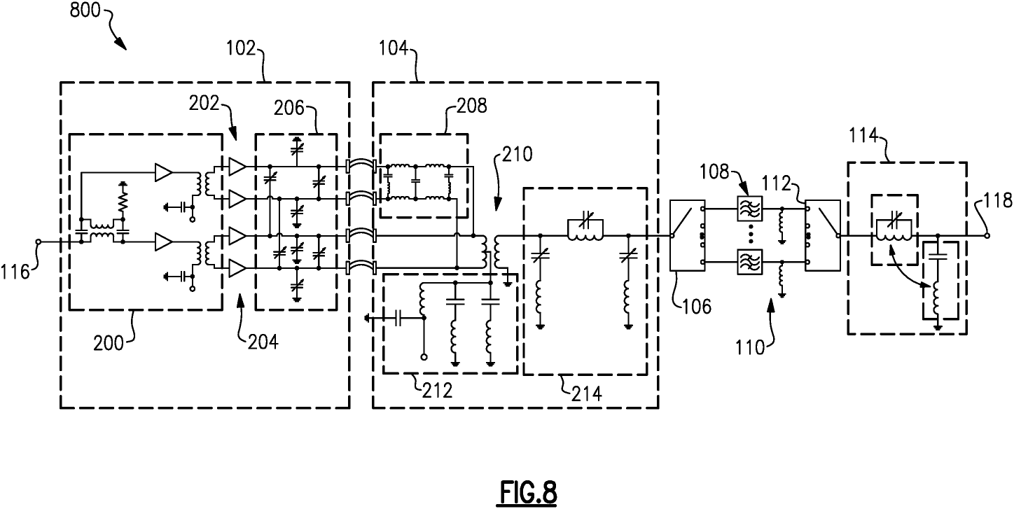

Various examples of components of the front-end module 100 have been illustrated at least in connection with FIGS. 2-7. FIG. 8 illustrates a schematic diagram of a front-end module 800 according to an example. The front-end module 800 may be an example of the front-end module 100 and may incorporate the various examples of components of the front-end module 100 discussed above, such as those illustrated in FIGS. 2 and 4-7. For example, the front-end module 800 includes the PA core 102, the output matching network 104, the BSW 106, the duplexers 108, the inductors 110, the ASM 112, the antenna matching network 114, the RF input 116, and the antenna output 118. The PA core 102 is illustrated in the front-end module 800 as including example components discussed in FIG. 2 including, for example, the power divider 200, the carrier-side amplifiers 202, the peaking-side amplifiers 204, and the shunt capacitors 206. Similarly, the output matching network 104 is illustrated in the front-end module 800 as including example components discussed in FIG. 2 including, for example, the inverter 208, the balun 210, the balun matching network 212, and the post-balun matching network 214.

Accordingly, examples of the disclosure provide improved harmonic impedance control for front-end modules which, in some examples, may include Doherty push-pull power amplifiers. Although certain solutions may implement post-balun components (for example, tanks and/or traps) to provide harmonic impedance control, various examples described herein may implement harmonic impedance control at a pre-balun inverter (for example, the inverter 208) and/or a balun-center-tapped matching network (for example, the balun matching network 212). Harmonic impedance control may be improved by implementing harmonic-impedance-control components closer to the outputs of one or more power amplifiers (for example, the carrier-side amplifiers 202 and/or the peaking-side amplifiers 204), because it may be less complex to match the output impedance of the one or more power amplifiers if fewer components are implemented between the one or more power amplifiers and the impedance-matching components. Accordingly, examples discussed herein provide improved harmonic impedance control.

As discussed above, the front-end module 100 may include, or be coupled to, a control circuit configured to control aspects of the front-end module 100 including, for example, tuning one or more capacitors. Various controllers may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A front-end module comprising:
an input configured to receive a radio-frequency signal;
an output configured to be coupled to an antenna;
a balun coupled to the output;
one or more power amplifiers coupled to the input; and
an inverter coupled between the one or more power amplifiers and the balun, the inverter being configured to provide output impedance matching to the one or more power amplifiers.

2. The front-end module of claim 1 wherein the inverter includes a first differential input and a second differential input coupled to the one or more power amplifiers, and a first differential output and a second differential output coupled to the balun.

3. The front-end module of claim 2 wherein the inverter includes a first capacitor having an input coupled to the first differential input and an output coupled to the first differential output, and a second capacitor having an input coupled to the second differential input and an output coupled to the second differential output.

4. The front-end module of claim 3 wherein the inverter includes a first inductor having an input coupled to the first differential input and an output,
a second inductor having an input coupled to the output of the first inductor and an output coupled to the first differential output, the first inductor and the second inductor forming a first series combination,
a third inductor having an input coupled to the second differential input and an output, and
a fourth inductor having an input coupled to the output of the third inductor and an output coupled to the second differential output, the third inductor and the fourth inductor forming a second series combination.

5. The front-end module of claim 4 wherein the first capacitor forms a first parallel combination with the first series combination of the first inductor and the second inductor, and the second capacitor forms a second parallel combination with the second series combination of the third inductor and the fourth inductor.

6. The front-end module of claim 5 wherein the first parallel combination presents an open circuit to at least one harmonic of a first fundamental signal received at the first differential input, and the second parallel combination presents an open circuit to at least one harmonic of a second fundamental signal received at the second differential input.

7. The front-end module of claim 6 wherein the first parallel combination presents an open circuit to second-order harmonics of the first fundamental signal and the second parallel combination presents an open circuit to second-order harmonics of the second fundamental signal.

8. The front-end module of claim 2 wherein the inverter includes
a first capacitor having an input coupled to the first differential input and an output,
a first inductor having an input coupled to the output of the first capacitor and an output coupled to the second differential input, the first inductor and the first capacitor forming a first series combination,
a second capacitor having an input coupled to the first differential output and an output, and
a second inductor having an input coupled to the output of the second capacitor and an output coupled to the second differential output, the second inductor and the second capacitor forming a second series combination.

9. The front-end module of claim 8 wherein the first series combination and the second series combination each present a short circuit to at least one harmonic of at least one of a first fundamental signal received at the first differential input or a second fundamental signal received at the second differential input.

10. The front-end module of claim 9 wherein the first series combination and the second series combination each present a short circuit to a third-order harmonic of at least one of the first fundamental signal or the second fundamental signal.

11. The front-end module of claim 1 wherein the balun includes a center tap, the front-end module further comprising a balun matching network coupled to the center tap of the balun.

12. The front-end module of claim 11 wherein the balun matching network includes
a first capacitor having an input coupled to the center tap of the balun and an output,
a first inductor having an input coupled to the output of the first capacitor and an output coupled to a reference node, the first capacitor and the first inductor forming a first series combination,
a second capacitor having an input coupled to the center tap of the balun and an output, and
a second inductor having an input coupled to the output of the second capacitor and an output coupled to the reference node, the second capacitor and the second inductor forming a second series combination.

13. The front-end module of claim 12 wherein at least one of the first series combination and the second series combination presents a short circuit to at least one of a fundamental signal at the center tap or at least one harmonic of the fundamental signal.

14. The front-end module of claim 13 wherein the first series combination presents a short circuit to the fundamental signal and the second series combination presents a short circuit to a third-order harmonic of the fundamental signal.

15. The front-end module of claim 12 wherein a parallel combination of the first series combination and the second series combination presents an open circuit to at least one harmonic of a fundamental signal at the center tap.

16. The front-end module of claim 15 wherein the parallel combination of the first series combination and the second series combination presents an open circuit to a second-order harmonic of the fundamental signal.

17. The front-end module of claim 1 further comprising a first power-amplifier balun and a second power-amplifier balun, the one or more power amplifiers including at least one first power amplifier coupled to the first power-amplifier balun and at least one second power amplifier coupled to the second power-amplifier balun.

18. A method of processing a radio-frequency signal comprising:
providing a front-end module having
an input configured to receive a radio-frequency signal,
an output configured to be coupled to an antenna,
a balun coupled to the output,
one or more power amplifiers coupled to the input, and
an inverter coupled between the one or more power amplifiers and the balun,
receiving, by the one or more power amplifiers from the input, the radio-frequency signal;
providing, by the one or more power amplifiers, an amplified signal to the inverter; and
providing, by the inverter, output impedance matching to the one or more power amplifiers responsive to receiving the amplified signal.

19. The method of claim 18 further comprising providing a balun matching network coupled to a center tap of the balun.

20. The method of claim 19 further comprising providing, by the balun matching network, output impedance matching to one or more signals conducted by the balun.
